(19) United States
(12) Patent Application Publication
(10) Pub. No.: US 2015/0185887 A1
(43) Pub. Date: Jul. 2, 2015

(54) TOUCH SENSOR AND METHOD OF MANUFACTURING THE SAME

(71) Applicant: SAMSUNG ELECTRO-MECHANICS CO., LTD., Gyeonggi-Do (KR)

(72) Inventors: Ho Joon PARK, Gyeonggi-Do (KR); Kyoung Soo CHAE, Gyeonggi-Do (KR); Sung Kwon WI, Gyeonggi-Do (KR)

(73) Assignee: SAMSUNG ELECTRO-MECHANICS CO., LTD., Gyeonggi-Do (KR)

(21) Appl. No.: 14/323,489

(22) Filed: Jul. 3, 2014

(30) Foreign Application Priority Data
Dec. 26, 2013 (KR) 10-2013-0164319

(51) Int. Cl. G06F 3/041; H05K 3/06; H05K 13/04; H05K 3/28

(52) U.S. Cl. CPC G06F 3/041; H05K 3/284; H05K 3/06; H05K 13/0469; G06F 2203/04103

(57) ABSTRACT

Embodiments of the invention provide a touch sensor and a method for manufacturing the touch sensor. The touch sensor, according to various embodiments of the invention, includes a base substrate, and an electrode pattern formed on the base substrate. The electrode pattern includes a first base layer stacked on the base substrate, a second electrode layer stacked on the first base layer, and a third protective layer stacked on the second electrode layer so as to enclose both side surfaces of the second electrode layer.

### CROSS REFERENCE TO RELATED APPLICATION

This application claims the benefit of and priority under 35 U.S.C. §119 to Korean Patent Application No. KR 10-2013-0164319, entitled “TOUCH SENSOR AND METHOD OF MANUFACTURING THE SAME,” filed on Dec. 26, 2013, which is hereby incorporated by reference in its entirety into this application.

### BACKGROUND

1. Field of the Invention

The present invention relates to a touch sensor and a method of manufacturing the same.

2. Description of the Related Art

In accordance with the growth of computers using a digital technology, devices assisting computers have also been developed, and personal computers, portable transmitters, other personal information processors execute processing of text and graphics using various input devices, such as a keyboard and a mouse.

In accordance with the rapid advancement of an information-oriented society, the use of computers has increased more and more. However, it is difficult to efficiently operate products using only a keyboard and a mouse currently serving as an input device. Therefore, the necessity for a device that is simple, has a less malfunction, and is capable of easily inputting information has increased.

In addition, techniques for input devices have progressed toward techniques related to high reliability, durability, innovation, designing and processing beyond the level of satisfying general functions. To this end, a touch sensor has been developed as an input device capable of inputting information, such as text and graphics.

This touch sensor is mounted on a display surface of a display, such as an electronic organizer, a flat panel display device including a liquid crystal display (LCD) device, a plasma display panel (PDP), an electroluminescence (El) element, as non-limiting examples, and a cathode ray tube (CRT), and is used to allow a user to select desired information while viewing the display.

In addition, the touch sensor is classified into a resistive type touch sensor, a capacitive type touch sensor, an electromagnetic type touch sensor, a surface acoustic wave (SAW) type touch sensor, and an infrared type touch sensor. These various types of touch sensors are adapted for electronic products in consideration of a signal amplification problem, a resolution difference, a level of difficulty of designing and processing technologies, optical characteristics, electrical characteristics, mechanical characteristics, environment-resistant characteristics, input characteristics, durability, and economic efficiency. Currently, the resistive type touch sensor and the capacitive type touch sensor have been prominently used in a wide range of fields.

Meanwhile, in a touch screen panel (TSP) field, electrodes of the touch sensor, which are transparent electrodes, have been made of an indium tin oxide (ITO), which has widely used. However, the transparent electrodes made of the ITO have made it difficult to implement a large touch sensor due to a high cost, a limit supply amount, and high resistance. Therefore, many studies and developments for replacing the transparent electrode have been conducted. Accordingly, various types of touch sensors have been suggested.

Among them, a metal mesh is appropriate for a touch sensor having a large area due to an advantage such as low resistance, but has low visibility due to opacity of patterns and is sensitive to moisture, such that it easily oxidized. Among them, it has been known that a method of forming an electrode using a metal mesh is the closest to commercialization. In order to replace an existing transparent electrode with the electrode using the metal mesh, reliability equal to or more than that of the existing transparent electrode has been demanded in the electrode using the metal mesh.

Meanwhile, as described in Japanese Patent Publication No. 2011-175967, a study for forming an electrode pattern using a metal has been actively conducted. As described above, when the electrode pattern is formed using the metal, electric conductivity is excellent and demand and supply is smooth. However, in the case in which the electrode pattern is formed using the metal, there was a problem that the electrode pattern may be visible to a user. Particularly, there were various problems such as a difficulty in implementing fine patterns due to a difference in an etching degree at lower portions of electrode patterns in a patterning process for forming the electrode patterns, visibility of the electrode patterns due to opacity of metal electrodes used for conductivity, a decrease in reliability due to low corrosion resistance of exposed electrode patterns.

### SUMMARY

Accordingly, embodiments of the invention have been made to provide a technology capable of improving characteristics for corrosion resistance and visibility of an electrode pattern by configuring the electrode pattern using three layers in a touch sensor including a metal electrode.

Further, embodiments of the invention have been made in an effort to provide a technology capable of supplementing visibility, which is a feature that a metal electrode is easily visible to eyes of a user, due to a twinkling feature of a metal itself, in a touch sensor having the metal electrode, with a protective layer of an electrode pattern.

Further, embodiments of the invention have been made in an effort to provide a technology capable of minimizing permeation of moisture, NaCl ions, and the like, by forming an electrode pattern in a structure in which the electrode layer having a relatively high etch rate is enclosed by a protective layer using the fact that the electrode layer has an etch rate higher than those of a base layer and the protective layer.

According to an embodiment of the invention, there is provided a touch sensor including a base substrate, and an electrode pattern formed on the base substrate. According to an embodiment, the electrode pattern includes a first base layer stacked on the base substrate, a second electrode layer stacked on the first base layer, and a third protective layer stacked on the second electrode layer to enclose both side surfaces of the second electrode layer.

According to an embodiment, the third protective layer of the electrode pattern has a reflectivity lower than that of the second electrode layer.

According to an embodiment, the first base layer and the third protective layer are at least one selected from a group consisting of a nickel-copper alloy (Ni—Cu), a nickel-chrome alloy (Ni—Cr), titanium (Ti), and chrome (Cr).

According to an embodiment, the base substrate is at least one selected from a group consisting of polyethylene terephthalate (PET), polycarbonate (PC), polymethyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, and tempered glass.

According to an embodiment, the electrode pattern is formed as a mesh pattern in which metal fine lines intersect with each other.

According to an embodiment, the touch sensor further includes an adhesive layer stacked on the electrode pattern, and a window substrate stacked on the adhesive layer.

According to another embodiment of the invention, there is provided a method of manufacturing a touch sensor. The method includes the steps of (A) preparing a base substrate, (B) forming a base layer on the base substrate, (C) forming an electrode layer on the base layer, (D) forming a protective layer on the electrode layer, (E) forming an electrode pattern by patterning the base layer, the electrode layer, and the protective layer, and (F) pressing both side surfaces of the patterned protective layer using a cushion so that the patterned protective layer encloses both side surfaces of the patterned electrode layer.

According to an embodiment, the protective layer of the electrode pattern has reflectivity lower than that of the electrode layer.

According to an embodiment, the base layer and the protective layer are at least one selected from a group consisting of a nickel-copper alloy (Ni—Cu), a nickel-chrome alloy (Ni—Cr), titanium (Ti), and chrome (Cr).

According to an embodiment, the base substrate is at least one selected from a group consisting of polyethylene terephthalate (PET), polycarbonate (PC), polymethyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, and tempered glass.

According to an embodiment, the electrode pattern is formed as a mesh pattern in which metal fine lines intersect with each other.

According to an embodiment, the method of manufacturing the touch sensor further includes, after (F) the pressing of both side surfaces of the patterned protective layer using the cushion, forming an adhesive layer on the electrode pattern, and forming a window substrate on the adhesive layer.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a cross-sectional view of an electrode pattern according to an embodiment of the present invention.

FIG. 2 is a plan view showing a structure of the electrode pattern according to an embodiment of the invention.

FIG. 3 is a cross-sectional view of a touch sensor according to an embodiment of the invention.

FIG. 4 is a cross-sectional view of a touch sensor according to an embodiment of the invention.

FIG. 5 is a cross-sectional view of a touch sensor according to an embodiment of the invention.

FIGS. 6 to 12 are cross-sectional views showing a manufacturing process flow in order to describe a method of manufacturing a touch sensor according to an embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing ligures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Hereinafter, various embodiments of the present invention will be described in detail with reference to the accompanying drawings.

Touch Sensor

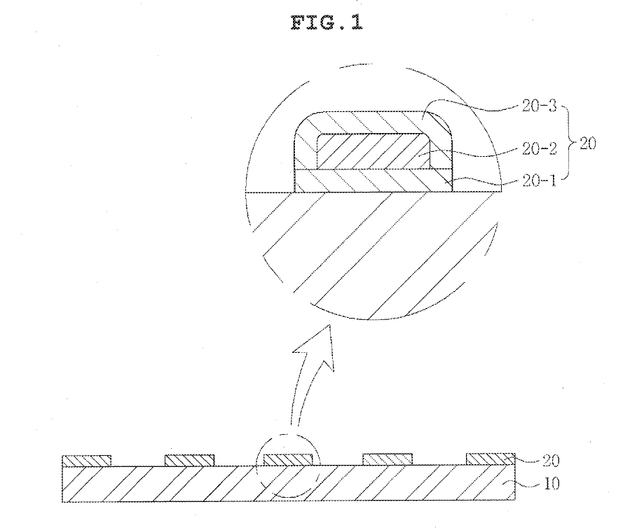

FIG. 1 is a cross-sectional view of an electrode pattern according to an embodiment of the invention.

Referring to FIG. 1, a touch sensor 100, according to an embodiment of the invention, is configured to include a base substrate 10, and an electrode pattern 20 formed on the base substrate 10. According to an embodiment, the electrode pattern 20 includes a first base layer 20-1 stacked on the base substrate 10, a second electrode layer 20-2 stacked on the first base layer 20-1, and a third protective layer 20-3 stacked on the second electrode layer 20-2 so as to enclose both side surfaces of the second electrode layer 20-2.

According to an embodiment, the first base layer 20-1 and the third protective layer 20-3 are at least one selected from a group consisting of a nickel-copper alloy (Ni—Cu), a nickel-chrome alloy (Ni—Cr), titanium (Ti), and chrome (Cr). In addition, the second electrode layer 20-2 is at least one selected from a group consisting of copper (Cu), aluminum (Al), and silver (Ag).

Since adhesion between the second electrode layer 20-2 and the base substrate 10 is low, the touch sensor 100, according to an embodiment of the invention, has a structure in which the first base layer 20-1 contacts an upper surface of the base substrate 10 in order to improve adhesion between the base substrate 10 and the electrode pattern 20.

According to an embodiment, the third protective layer 20-3 of the electrode pattern 20 has a reflectivity lower than that of the second electrode layer 20-2. According to an embodiment, the second electrode layer 20-2 is made of a metal material having good conductivity. However, the metal material that may be used in the second electrode layer 20-2 may be easily viewed to eyes of a user due to high reflectivity.

Therefore, the electrode pattern 20, according to an embodiment, has a structure in which the third protective layer 20-3 made of a dark metal material encloses an upper surface and both side surfaces of the second electrode layer 20-2 in order to lower the reflectivity of the metal material used in the second electrode layer 20-2.

According to an embodiment, the electrode pattern 20 is formed as a mesh pattern in which metal fine lines intersect with each other, and the mesh pattern is not limited to having a specific shape, but has, for example, a polygonal shape, such as a rectangular shape, a triangular shape, or a diamond shape, as non-limiting examples.

According to an embodiment, the third protecting layer 20-3 made of, for example, an alloy of different metals for preventing corrosion of the electrode pattern 20 is stacked on the second electrode layer 20-2 to enclose the upper surface and both side surfaces of the second electrode layer 20-2 to minimize permeation of moisture and NaCl ions into the second electrode layer 20-2, thereby making it possible to prevent the corrosion of the electrode pattern 20.

According to an embodiment, the base substrate 10 is not particularly limited, but is at least one selected from a group consisting of polyethylene terephthalate (PET), polycarbonate (PC), polymethyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, and tempered glass.

In addition, although not shown in FIG. 1, the touch sensor 100, according to an embodiment of the invention, further includes an adhesive layer stacked on the electrode pattern 20 and a window substrate stacked on the adhesive layer, but is not particularly limited thereto.

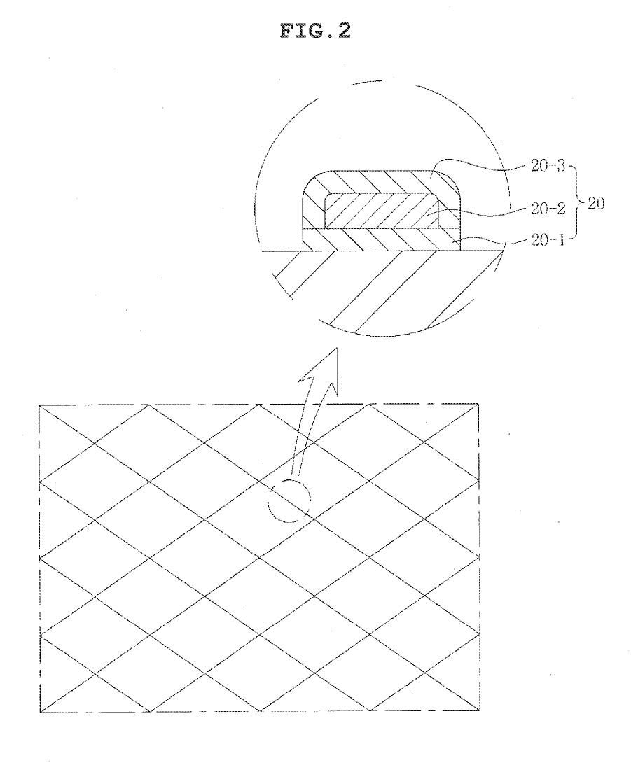

FIG. 2 is a plan view showing a structure of the electrode pattern according to an embodiment of the invention.

Referring to FIG. 2, the electrode pattern 20, according to an embodiment of the invention, is formed as the mesh pattern in which the metal fine lines intersect with each other. In addition, the mesh pattern is not limited to having a specific shape, but has a polygonal shape, such as a rectangular shape, a triangular shape, or a diamond shape, as non-limiting examples. Further, the electrode pattern 20 stacked on the base substrate 10 has a cross-sectional structure in which the first base layer 20-1, the second electrode layer 20-2, and the third protective layer 20-3 are sequentially stacked.

According to an embodiment, the electrode pattern 20 is configured using a total of three layers, for example, the first base layer 20-1, the second electrode layer 20-2, and the third protective layer 20-3. Therefore, adhesion between the base substrate 10 and the electrode pattern 20 is improved through the first base layer 20-1 contacting the upper surface of the base substrate 10. In addition, the third protective layer 20-3 encloses the upper surface and both side surfaces of the second electrode layer 20-2 to improve a problem of visibility, thereby making it possible to prevent corrosion of the second electrode layer 20-2.

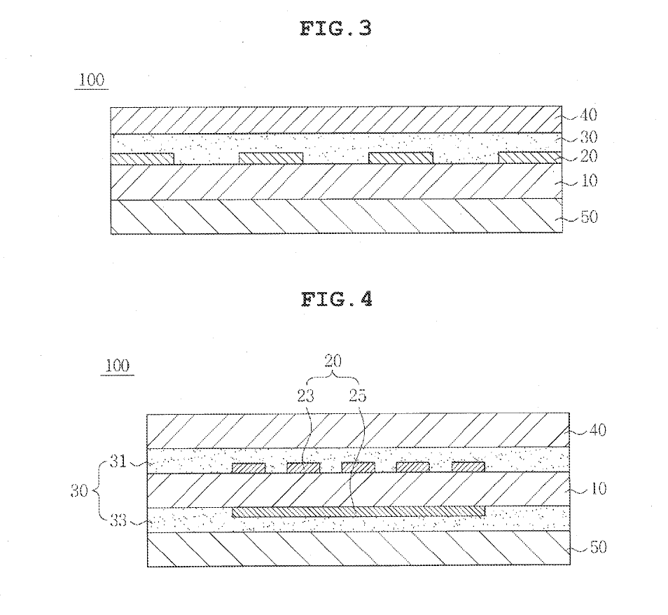

FIG. 3 is a cross-sectional view of a touch sensor according to an embodiment of the invention.

Referring to FIG. 3, the touch sensor 100, according to an embodiment of the invention, includes the base substrate 10 and the electrode pattern 20 formed on one surface of the base substrate 10.

According to an embodiment, the touch sensor 100 includes a display part 50 formed on the other surface of the base substrate 10 in order to display an output value that the user inputs through the touch sensor 100. Further, the touch sensor 100 includes a window substrate 40 formed on the outermost layer thereof in order to protect the electrode pattern 20 and further includes an adhesive layer 30 formed in order to adhere the window substrate 40 and the base substrate 10 including the electrode pattern 20 to each other.

According to an embodiment, the display part 50, which is an image device, includes various display devices, such as a liquid crystal display (LCD) or an organic light emitting diode (OLED), as non-limiting examples, but is not limited to a specific kind of device.

According to an embodiment, the window substrate 40 is made of, for example, tempered glass, as a non-limiting example, and is formed by coating using a material that may perform a protection role.

According to an embodiment, the adhesive layer 30 is not particularly limited, but is made of an optically clear adhesive (OCA).

Since contents of the base substrate and the electrode pattern are the same as those of the base substrate and the electrode pattern described above, a detailed description thereof will be omitted.

FIG. 4 is a cross-sectional view of a touch sensor according to another embodiment of the invention.

Referring to FIG. 4, a touch sensor 100, according to another embodiment of the invention, is configured to include a base substrate 10, a first electrode pattern 23 formed on one surface of the base substrate 10, and a second electrode pattern 25 formed on the other surface of the base substrate 10 to intersect with the first electrode pattern 23.

According to an embodiment, the touch sensor 100 includes a window substrate 40 formed on the outermost layer thereof in order to protect the electrode pattern 20 and further includes a first adhesive layer 31 formed in order to adhere the window substrate 40 and the base substrate 10 including the first electrode pattern 23 to each other. Further, the touch sensor 100 includes a display part 50 formed on the other surface of the base substrate 10 in order to display an output value that the user inputs through the touch sensor 100 and further includes a second adhesive layer 33 formed in order to adhere the display part 50 and the base substrate 10 including the second electrode pattern 25 to each other.

Since contents of the base substrate, the first electrode pattern, the second electrode pattern, the first adhesive layer, the second adhesive layer, the window substrate, and the display part are the same as those of the base substrate, the electrode pattern, and the adhesive layer, the window substrate, and the display part described above, a detailed description thereof will be omitted.

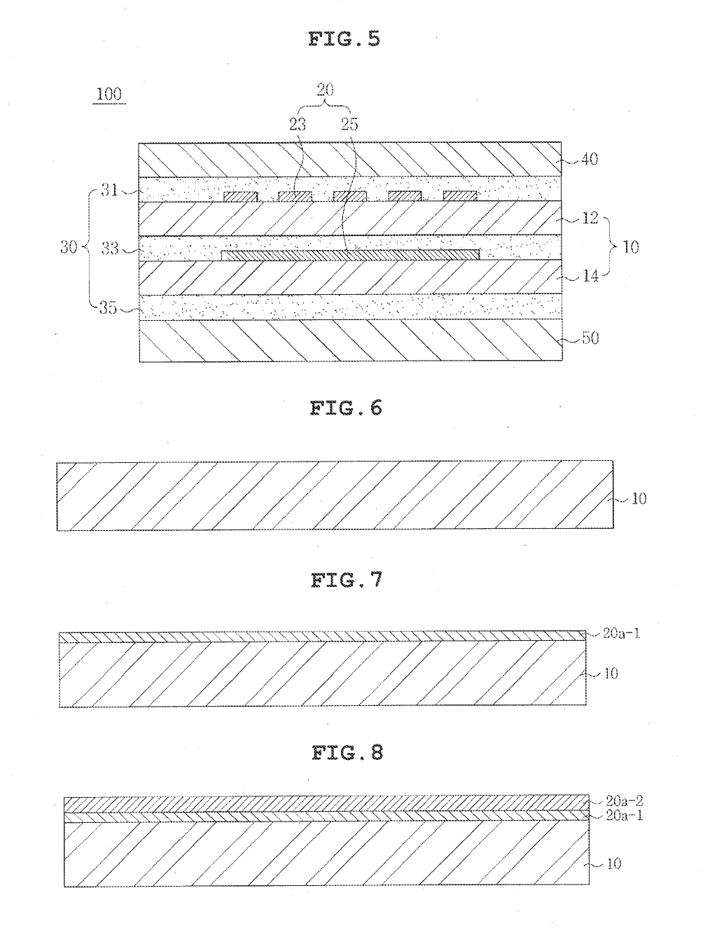

FIG. 5 is a cross-sectional view of a touch sensor according to still another embodiment of the invention.

Referring to FIG. 5, a touch sensor 100, according to still another embodiment of the invention, is configured to include a first base substrate 12, a second base substrate 14, a first electrode pattern 23 formed on the first base substrate 12, and a second electrode pattern 25 formed on the second base substrate 14 to face the first electrode pattern 23 and intersect with the first electrode pattern 23. The first base substrate 12 and the second base substrate 14 are coupled to each other by a second adhesive layer 33, such that the touch sensor 100 may be manufactured.

According to an embodiment, the touch sensor 100 includes a window substrate 40 formed on the outermost layer thereof in order to protect the first electrode pattern 23 and further includes a first adhesive layer 31 formed in order to adhere the window substrate 40 and the base substrate 10 including the first electrode pattern 23 to each other.

According to an embodiment, the touch sensor 100 includes a display part 50 formed on the other surface of the base substrate 10 in order to display an output value that the user inputs through the touch sensor 100 and further includes a third adhesive layer 35 formed in order to adhere the display part 50 and the base substrate 10 including the second electrode pattern 25 to each other.

Since contents of the first base substrate, the second base substrate, the first electrode pattern, the second electrode pattern, the first adhesive layer, the second adhesive layer, the third adhesive layer, the window substrate, and the display part are the same as those of the base substrate, the electrode pattern, and the adhesive layer, the window substrate, and the display part described above, a detailed description thereof will be omitted.

Method of Manufacturing Touch Sensor

FIGS. 6 to 12 are cross-sectional views showing a manufacturing process flow in order to describe a method of manufacturing a touch sensor according to an embodiment of the invention.

A method of manufacturing a touch sensor 100, according to an embodiment of the invention, includes preparing a base substrate 10, forming a base layer 20a-1 formed on the base substrate 10, forming an electrode layer 20a-2 formed on the base layer 20a-1, forming a protective layer 20a-3 on the electrode layer 20a-2, forming an electrode pattern 20 by patterning the base layer 20a-1, the electrode layer 20a-2, and the protective layer 20a-3, and pressing both side surfaces of the patterned protective layer using a cushion so that the patterned protective layer encloses both side surfaces of the patterned electrode layer.

Referring to FIG. 6, the method of manufacturing a touch sensor 100, according to an embodiment of the invention, includes preparing the base substrate 10.

According to an embodiment, the base substrate 10 is not particularly limited, but is at least one selected from a group consisting of polyethylene terephthalate (PET), polycarbonate (PC), polymethyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, and tempered glass.

Referring to FIG. 7, the method of manufacturing a touch sensor 100, according to an embodiment of the invention, includes forming the base layer 20a-1 on the base substrate 10.

According to an embodiment, the base layer 20a-1 is not particularly limited, but is at least one selected from a group consisting of a nickel-copper alloy (Ni—Cu), a nickel-chrome alloy (Ni—Cr), titanium (Ti), and chrome (Cr). In addition, in forming the electrode pattern 20 on the base substrate 10, when the electrode layer 20a-2 is directly formed on the base substrate 10, the electrode pattern 20 is not appropriately adhered to the base substrate 10, such that the electrode pattern 20 is easily separated from the base substrate 10. Therefore, the base layer 20a-1 is first formed on the base substrate 10, thereby making it possible to maintain adhesion between the base substrate 10 and the electrode pattern 20.

Referring to FIG. 8, the method of manufacturing a touch sensor 100, according to an embodiment of the invention, includes forming the electrode layer 20a-2 on the base layer 20a-1.

According to an embodiment of the invention, the electrode layer 20a-2 is not particularly limited, but is at least one selected from a group consisting of copper (Cu), aluminum (Al), and silver (Ag). The electrode layer 20a-2 has excellent electrical conductivity.

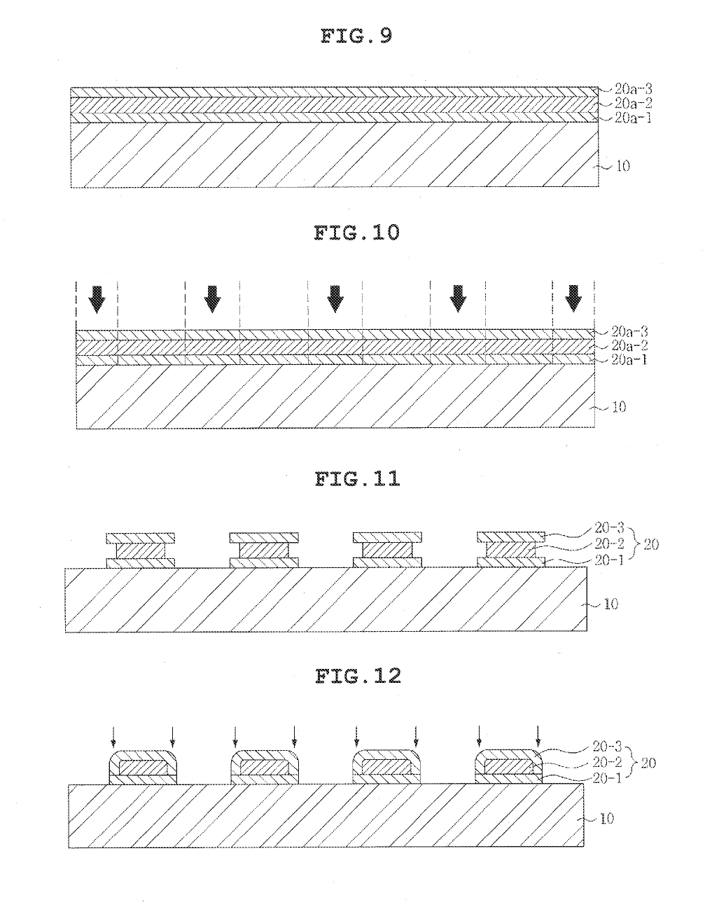

Referring to FIG. 9, the method of manufacturing a touch sensor 100, according to an embodiment of the invention, includes forming the protective layer 20a-3 on the electrode layer 20a-2.

According to an embodiment, the protective layer 20a-3 is at least one selected from a group consisting of a nickel-copper alloy (Ni—Cu), a nickel-chrome alloy (Ni—Cr), titanium (Ti), and chrome (Cr), similar to the base layer 20a-1, but is not particularly limited thereto.

According to an embodiment, the protective layer 20a-3 has a reflectivity lower than that of the electrode layer 20a-2. Therefore, the protective layer 20a-3 having a feature of a dark color is formed on the electrode layer 20a-2, thereby making it possible to supplement visibility of the electrode layer 20a-2, that is, a feature that the electrode layer 20a-2 is easily visible to eyes of the user due to a twinkling feature of a metal material configuring the electrode layer 20a-2.

According to an embodiment, the base layer 20a-1, the electrode layer 20a-2, and the protective layer 20a-3 are formed on the base substrate 10 by a dry process, a wet process, or a direct patterning process. The dry process includes, for example, a sputtering process, or an evaporation process, as non-limiting examples, the wet process includes, for example, a dip coating process, a spin coating process, a roll coating process, or a spray coating process, as non-limiting examples, and the direct patterning process includes, for example, a screen printing process, a gravure printing process, or an inkjet printing process, as non-limiting examples.

According to an embodiment, the electrode pattern 20 of the touch sensor 100, according to an embodiment of the invention, is formed as a mesh pattern in which metal fine lines intersect with each other. In addition, the mesh pattern is not limited to having a specific shape, but has, for example, a polygonal shape, such as a rectangular shape, a triangular shape, or a diamond shape, as non-limiting examples.

Referring to FIG. 10, the method of manufacturing a touch sensor 100, according to an embodiment of the invention, includes forming the electrode pattern 20 by patterning the base layer 20a-1, the electrode layer 20a-2, and the protective layer 20a-3.

A method of the patterning is as follows. According to an embodiment, a photosensitive material is applied onto a substrate using a photolithograph and light is irradiated using a mask formed in a desired pattern. Then, a developing process for forming a desired pattern, for example, removing a portion of the photosensitive material to which the light is irradiated using a developer, removing a portion of the photosensitive material to which the light is not irradiated using, for example, a developer, is performed. Then, the photosensitive material is formed in a specific pattern, and the remaining portion is removed by an etchant by using the photosensitive material as a resist. Then, when the photosensitive material is removed, the electrode pattern 20 having a desired pattern is formed.

Referring to FIG. 11, the method of manufacturing a touch sensor 100, according to an embodiment of the invention, includes forming the electrode pattern 20 on the base substrate 10 through the patterning. In the forming of the electrode pattern 20, since the electrode layer 20a-2 and the protective layer 20a-3 are made of different metal materials, there is a difference in an etch rate between the electrode layer 20a-2 and the protective layer 20a-3. In detail, the electrode layer 20a-2 has an etch rate higher than that of the protective layer 20a-3. Therefore, in the forming of the electrode pattern 20 by patterning the base layer 20a-1, the electrode layer 20a-2, and the protective layer 20a-3, the electrode layer 20a-2 having a structure in which the electrode layer 20a-2 is further etched as compared with the base layer 20a-1 and the protective layer 20a-3 are formed.

Referring to FIG. 12, the method of manufacturing a touch sensor 100, according to an embodiment of the invention, includes pressing both side surfaces of the patterned protective layer using the cushion, so that the patterned protective layer encloses the upper surface and both side surfaces of the patterned electrode layer. According to an embodiment, the cushion indicates a member having elasticity and applies pressure at a level at which the base layer 20a-1, the electrode layer 20a-2, and the protective layer 20a-3 are not damaged, thereby making it possible to perform a process.

Therefore, the second electrode layer 20-2 is enclosed by the third protective layer 20-3 having a dark color, thereby making it possible to improve visibility of the second electrode layer 20-2, thus, a feature that the second electrode layer 20-2 is easily visible to eyes of the user due to a twinkling feature of the second electrode layer 20-2, and the upper surface and both side surfaces of the second electrode layer 20-2 is enclosed by the third protective layer 20-3, thereby making it possible to prevent permeation of, for example, moisture and NaCl ions, as non-limiting examples.

The method of manufacturing a touch sensor 100, according to an embodiment of the invention, further includes, after the pressing both side surfaces of the patterned protective layer using the cushion, forming an adhesive layer 30 on the electrode pattern 20 and forming a window substrate 40 on the adhesive layer 30.

In the touch sensor including the metal electrode, according to an embodiment of the invention, the electrode pattern is configured using three layers, thereby making it possible to improve corrosion resistance and visibility of the electrode pattern.

In addition, visibility, that is, a feature that the metal electrode is easily visible to eyes of a user due to a twinkling feature of a metal itself, in the touch sensor having the metal electrode may be supplemented with the protective layer of the electrode pattern.

Further, the electrode pattern is formed in a structure in which the upper surface and both side surfaces of the second electrode layer having a relatively high etch rate are enclosed by the third protective layer using the fact that the second electrode layer has an etch rate higher than those of the first base layer and the third protective layer, thereby making it possible to minimize permeation of, for example, moisture and NaCl ions, as non-limiting examples.

Further, the base layer at a portion of the electrode pattern adhered to the base substrate is formed of a thin film of an alloy layer containing nickel (Ni), thereby making it possible to improve adhesion between the base substrate and the electrode pattern.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A touch sensor, comprising:
a base substrate; and
an electrode pattern formed on the base substrate,
wherein the electrode pattern includes:
a first base layer stacked on the base substrate;
a second electrode layer stacked on the first base layer; and
a third protective layer stacked on the second electrode layer so as to enclose both side surfaces of the second electrode layer.

2. The touch sensor as set forth in claim 1, wherein the third protective layer of the electrode pattern has a reflectivity lower than that of the second electrode layer.

3. The touch sensor as set forth in claim 1, wherein the first base layer and the third protective layer are at least one selected from a group consisting of a nickel-copper alloy (Ni—Cu), a nickel-chrome alloy (Ni—Cr), titanium (Ti), and chrome (Cr).

4. The touch sensor as set forth in claim 1, wherein the base substrate is at least one selected from a group consisting of polyethylene terephthalate (PET), polycarbonate (PC), polymethyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, and tempered glass.

5. The touch sensor as set forth in claim 1, wherein the electrode pattern is formed as a mesh pattern in which metal fine lines intersect with each other.

6. The touch sensor as set forth in claim 1, further comprising:
an adhesive layer stacked on the electrode pattern; and
a window substrate stacked on the adhesive layer.

7. A method of manufacturing a touch sensor, comprising:
(A) preparing a base substrate;
(B) forming a base layer on the base substrate;
(C) forming an electrode layer on the base layer;
(D) forming a protective layer on the electrode layer;
(E) forming an electrode pattern by patterning the base layer, the electrode layer, and the protective layer; and
(F) pressing both side surfaces of the patterned protective layer using a cushion so that the patterned protective layer encloses both side surfaces of the patterned electrode layer.

8. The method of manufacturing a touch sensor as set forth in claim 7, wherein the protective layer of the electrode pattern has reflectivity lower than that of the electrode layer.

9. The method of manufacturing a touch sensor as set forth in claim 7, wherein in (E) the forming of the electrode pattern, the electrode layer has an etch rate higher than that of the protective layer.

10. The method of manufacturing a touch sensor as set forth in claim 7, wherein the base layer and the protective layer are at least one selected from a group consisting of a nickel-copper alloy (Ni—Cu), a nickel-chrome alloy (Ni—Cr), titanium (Ti), and chrome (Cr).

11. The method of manufacturing a touch sensor as set forth in claim 7, wherein the base substrate is at least one selected from a group consisting of polyethylene terephthalate (PET), polycarbonate (PC), polymethyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, and tempered glass.

12. The method of manufacturing a touch sensor as set forth in claim 7, wherein the electrode pattern is formed as a mesh pattern in which metal fine lines intersect with each other.

13. The method of manufacturing a touch sensor as set forth in claim 7, further comprising:
after (F) the pressing of both side surfaces of the patterned protective layer using the cushion, forming an adhesive layer on the electrode pattern; and
forming a window substrate on the adhesive layer.
